(19) United States
(12) Patent Application Publication
(10) Pub. No.: US 2026/0372111 A1
(43) Pub. Date: Nov. 19, 2026

(54) ALIGNMENT MARKS FOR SEMICONDUCTOR DEVICES

(71) Applicant: Taiwan Semiconductor Manufacturing Company, Ltd., Hsinchu (TW)

(72) Inventors: Chen-Chin Liu, New Taipei City 242 (TW); Kuo-Chyuan Tzeng, Hsinchu (TW); Jer-Yi Lin, Hsinchu (TW)

(73) Assignee: Taiwan Semiconductor Manufacturing Company, Ltd., Hsinchu (TW)

(21) Appl. No.: 19/209,105

(22) Filed: May 15, 2025

(51) Int. Cl. H10W 46/00; H10W 20/00

(52) U.S. Cl. CPC H10W 46/00; H10W 20/056; H10W 20/075; H10W 20/081; H10W 46/301

(57) ABSTRACT

A method of semiconductor device fabrication is provided. The method includes forming a first etch stop layer over a substrate. The method includes forming an inter-layer dielectric over the etch stop layer. The method includes patterning the inter-layer dielectric to form a first opening and a second opening. The method includes forming a second etch stop layer over the patterned inter-layer dielectric. The method includes forming an anti-reflective layer over the first etch stop layer, the anti-reflective layer having a first thickness over the first opening, and a second thickness, greater than the first thickness, over the second opening. The method includes etching the anti-reflective layer to expose a bottom surface of the second opening, the anti-reflective layer covering the bottom surface of the first opening.

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductor layers of material over a substrate, and patterning the various material layers using lithography to form circuit components and elements thereon. As the semiconductor industry has progressed into nanometer technology process nodes in pursuit of higher device density, improved performance, and lower costs, challenges from both fabrication and design issues have resulted in the development of stacked substrates, such as in the case of wafer or die bonding. Accordingly, various components of a circuit may be distributed between substrates. Alignment marks can provide a fiducial indication to identify a relative lateral portion of a device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example flow chart of a method for semiconductor device fabrication, in accordance with some embodiments.

FIGS. 2-7 illustrate example cross sectional views of a semiconductor device during various fabrication stages according to the method of FIG. 1, in accordance with some embodiments.

FIG. 8 illustrates an example cross sectional view of a semiconductor device including stacked layers, as may be formed during according to the method of FIG. 1, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Generally, alignment marks (sometimes referred to as a fiducial markings) can be provided to identify an edge or other portion of a semiconductor device. For example, semiconductor devices, including stacked memory devices, can include alignment marks to aid in their stacking or bonding, to maintain a position of stacked components which can thermally or electrically connect with one another. Such stacking can refer to stacking of two or more substrates, such as backside or frontside bonding, or providing further layers over a semiconductor device. Thicker alignment marks may be more readily identified, as may aid with the alignment of various layers over one another.

According to the present disclosure, rather than defining an opening for the alignment mark according to a lithographic mask, the alignment mark can be formed according to a non-uniform distribution of an anti-reflective coating. For example, a spin-coating process can accumulate a greater thickness of an organic backside anti-reflective coating (oBARC) over portions of a semiconductor device including few or small openings, relative to larger openings. Accordingly, larger openings associated with alignment marks can receive a thickness of the oBARC which is less than a thickness for other portions of the semiconductor device (e.g., a portion formed over memory cells or device logic). The greater thickness can protect the memory cells or device logic from a removal process used to form or extend an opening for an alignment mark, obviating the separate mask used to define the alignment mark. Such a technique can omit a separate mask to define the alignment mark openings, and can further define a deeper opening so that a thicker alignment mark can be formed, aiding in identification of the alignment mark relative to other approaches.

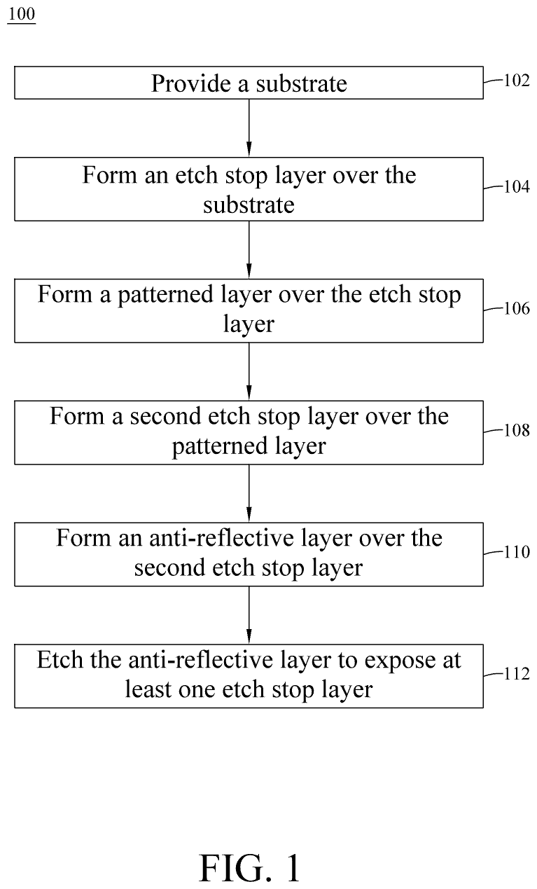

FIG. 1 illustrates a flow diagram for a method 100 of semiconductor device fabrication, in accordance with some embodiments. For example, at least some of the operations (or steps) of the method 100 may be used to form a semiconductor device including an alignment mark. It should be noted that the method 100 is merely an example, and is not intended to limit the present disclosure. Accordingly, it is understood that additional operations may be provided before, during, or after the method 100 of FIG. 1, and that some other operations may only be described briefly described herein.

In brief overview, the method 100 starts with operation 102 of providing a substrate. Next, the method 100 proceeds to operation 104 of forming an etch stop layer over the substrate. Next, the method 100 proceeds to operation 106 of forming a patterned layer over the etch stop layer. Next, the method 100 proceeds to operation 108 of forming a second etch stop layer over the patterned layer. Next, the method 100 proceeds to operation 110 of forming an anti-reflective layer over the second etch stop layer. Next, the method 100 proceeds to operation 112 of etching the anti-reflective layer to expose at least one etch stop layer.

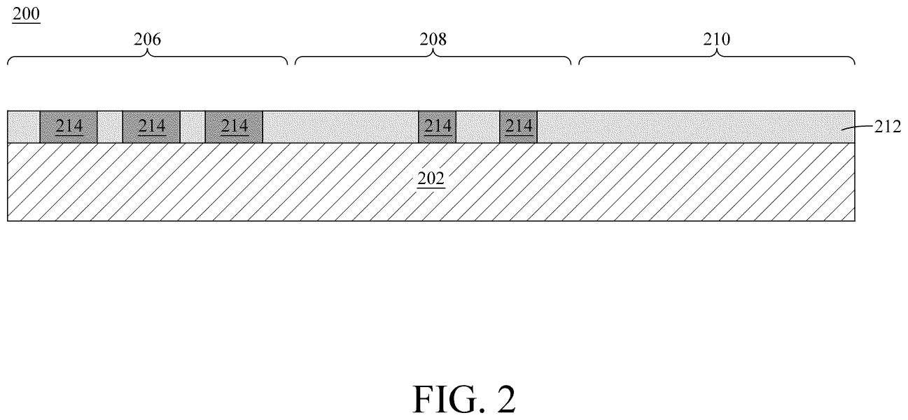

Corresponding to operation 102 of FIG. 1, FIG. 2 illustrates a semiconductor device 200 substrate including a substrate 202. The substrate 202 can include an active surface, over which various components can be formed. For example, the active surface can include transistors, diodes, resistors, or capacitors electrically interconnected to form circuits. The active surface of the semiconductor device 200 can include various regions according to a function of the circuits. For example, a first region 206 of the semiconductor device 200 can include memory cells. A second region 208 of the semiconductor device 200 can include circuits of a processor or other logic for processing circuity. A third region 210 of the semiconductor device 200 can be reserved for an alignment mark, as may aid positioning of the semiconductor device 200. For example, the alignment mark can be provided as a fiducial marking to aid in the forming of further layers stocked over the semiconductor device.

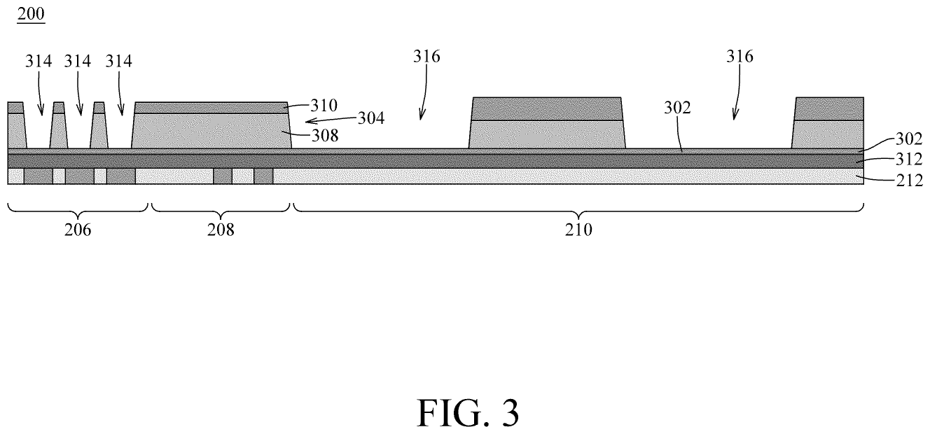

Although depicted as roughly equal in lateral dimension in the present figure, with the third region 210 depicted more prominently in FIGS. 3-8, the areas associated with the respective regions can vary greatly. For example, area dedicated to alignment marks is generally small (e.g., one percent device area). Accordingly, the first region 206 and second region 208 can make up a majority of a device, as may vary according to a device type. For example, in an illustrative example, the first region 206 can make up about five percent of a device area, and the second region 208 can make up about ninety-five percent.

The depicted substrate 202 can be provided with any number of stacked layers, as may include further active surfaces coupled with one another by via structures 214. The via structures 214 can be provided as backside or other through substrate vias (sometimes referred to as a through silicon vias). An inter-layer dielectric, as may include a low-k dielectric 212, can provide electrical separation of the various components of the layers, to reduce cross-talk or other electro-magnetic coupling/interference between the layers. In some embodiments, the low-k dielectric 212 is provided as an extreme low-k dielectric (having a k-value of less than 2.5). For example, Organosilicate Glass (OSG), Fluorinated Silicon Oxide (SiOF), spin on polymers or various porous materials can be used. The low-k dielectric 212 can be formed over a surface of the semiconductor device (e.g., a backside, opposite from an active surface of the front side).

Some of the via structures 214 are depicted extending vertically through the first region 206, as may be provided to couple with various further memory cells stacked thereover, or to form interconnects between the various memory cells. Further via structures 214 are depicted extending through the second region 208, as may be provided to couple with various further devices or logic, or to form interconnects. The via structures 214 can be provided as backside vias, according to various illustrative examples of the present disclosure. However, such references should not be construed as limiting. Aspects of the current disclosure can be applied with respect to frontside bonding or stacking, or other processes.

Corresponding to operations 104-106 of FIG. 1, FIG. 3 illustrates a cross-sectional view of a semiconductor device 200 including a patterned layer 304 formed at operation 106. The patterned layer 304 is formed over a first etch stop layer 302, which is formed at operation 104.

Referring to the first etch stop layer 302 (sometimes referred to as a cap layer), the first etch stop layer 302 can be provided as an aluminum oxide layer. The aluminum oxide layer can be formed according to an atomic layer deposition (ALD) process, as can provide adequate process control for a relatively thin layer, such as about 40 Angstroms. For example, 40 cycles of an ALD process can be repeated to form the first etch stop layer. Some embodiments can apply the aluminum oxide layer according to further processes, such as chemical or physical vapor deposition vapor deposition (CVD/PVD). Such processes can provide a layer in fewer cycles (e.g., a single cycle). however, such approaches can provide reduced process control relative to the ALD process. In some embodiments, an etch stop layer (e.g., the first etch stop layer 302) can include another material. For example, an etch stop layer can include hafnium oxide or zirconium oxide, among others.

The first etch stop layer 302 can be formed directly over a substrate (e.g., the substrate pictured in FIG. 2), or can be deposited over further layers. For example, various first etch stop layers 302 can be formed over repeating stacks of the layers depicted in FIGS. 2-7, to form a stacked memory device. The stacked memory device can include a silicon-based layer, as may include a semiconductive material to form an active surface, or various hardmasks 312 or stress compensation layers. For example, such a silicon-based layer can include a hardmask 312 including silicon oxynitride, silicon carbide, or silicon carbonitride, having a thickness of about 150 angstroms.

Referring to the patterned layer 304, the patterned layer 304 can include an interlayer dielectric (ILD). The inter-layer dielectric can include, for example, undoped silicate glass (USG) formed according to CVD process, such as plasma enhanced CVD, or low-pressure CVD. In some embodiments, the ILD can be formed as having a thickness of about 650 angstroms. Various openings can be formed to generate the patterned layer 304 according to various positive or negative photolithographic processes. The patterned layer 304 can include one or more constituent layers, as may include a layer to aid process control of the lithography. For example, the patterned layer 304 can include a first layer 308 of the ILD and a second layer 310 of an anti-reflective coating. The anti-reflective coating can include a negative tone bottom anti-reflective coating (NFARC) having a thickness of about 330 angstroms.

The openings can be formed having varied lateral widths according to the lithographic process. For example, one or more first openings 314 can be formed over the first region 206 of the substrate, over memory cells or logic elements. The first openings 314 can be formed to receive further via structures or other interconnects. At least one second opening 316 can be formed over the third region 210. The second opening 316 can be formed to receive an alignment mark. The second opening 316 can exhibit greater lateral width than the first openings (e.g., at least an order of magnitude greater). The various opening widths can be defined according to a mask used for the positive or negative lithographic process used to pattern the patterned layer 304.

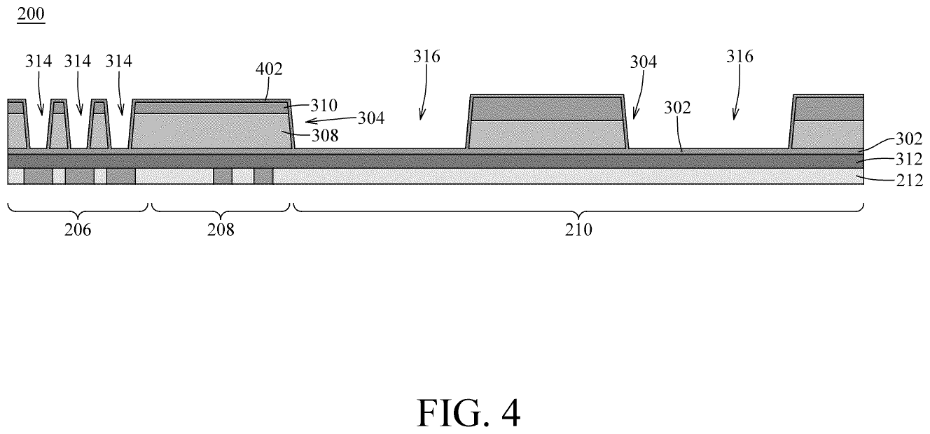

Corresponding to operation 108 of FIG. 1, FIG. 4 illustrates a semiconductor device 200 having a second etch stop layer 402 formed over the patterned layer 304. The second etch stop layer 402 can be provided as a same material as the first etch stop layer (e.g., aluminum oxide), or can be provided as a different material. A thickness of the second etch stop layer 402 can vary from the thickness of the first etch stop layer. For example, the second etch stop layer 402 can be provided at about half of the thickness of the first etch stop layer 302 (e.g., about 20 angstroms of aluminum oxide). A total etch stop thickness can vary between the bottom surfaces of the openings and an upper surface of the patterned layer 304. For example, at the bottom surfaces of the openings, the second etch stop layer 402 can form additively over the first etch stop layer 302 (although some portion of the first etch stop layer 302 may be affected by the patterning of the patterned layer 304). Conversely, the portion of the second etch stop layer 402 formed over the upper surface of the patterned layer 304 should not include any contribution of the first etch stop layer 302. Accordingly, etch stop formed over the patterned layer can be provided according to a deposition thickness of the second etch stop layer 402, at least where the patterned layer does not itself include a constituent etch stop along an upper surface.

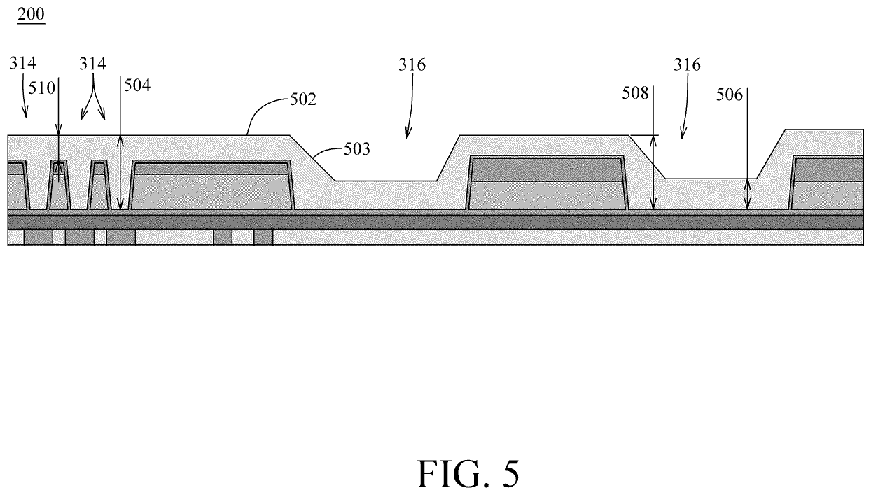

Corresponding to operation 110 of FIG. 1, FIG. 5 illustrates a semiconductor device 200 having an anti-reflective layer 502 formed over the second etch stop layer 402. For example, the anti-reflective layer 502 can be formed as an organic back anti-reflective coating oBARC, deposited according to a spin-coating process, or an inorganic back anti-reflective coating iBARC, deposited according to a CVD deposition process.

As is depicted, the anti-reflective layer 502 exhibits shallower taper than the patterned layer 304. That is, a sidewall 503 of the anti-reflective layer 502 is shallower than a sidewall 505 of the first openings 314 or the second openings 316. Accordingly, the anti-reflective layer 502 can form a relatively level upper surface over the (laterally smaller) first openings 314, and exhibit greater taper over the (laterally larger) second openings 316, where the lateral dimension of the second openings 316 exceeds a lateral dimension of the tapered sidewalls of the anti-reflective layer 502. For example, a dimension of a lateral surface of a bottom of a second opening 316, formed between corresponding sidewalls 503, can exceed a lateral dimension of a bottom of the anti-reflective layer 502 (the bottom of the anti-reflective layer 502 formed above the bottom of the second opening 316). A first distance 504 (or thickness) from a bottom surface of a lateral center of a first opening 314 can exceed a second thickness 506 (or distance) from a bottom surface of a lateral center of a second opening 316. The difference can correspond approximately to a thickness of the patterned layer 304. For example, for a patterned layer 304 having a 650 angstrom ILD and a 330 angstrom NFARC, the first distance 504 and second difference can deviate by about 980 angstroms (~100 nm). Accordingly, as measured along a sidewall of the second opening 316, a third distance 508 (or thickness) can be approximately equal to the first distance 504.

For application of anti-reflective layers 502, especially for spin-coating processes used to apply oBARC, the anti-reflective layers 502 can clump over the existing high spot of the patterned layer 304 proximal to the first openings 314. Such clumping may lead to somewhat greater accumulation of material over the first region 206 (or second region 208), relative to the third region 210. Such an effect can be amplified by reducing spin speeds (e.g., to about 1 k-2 k RPM), or according to a multistep spin profile, beginning at less than about 1 k RPM (e.g., about 500 RPM) and ramping to about 2 k RPM. Further, increased BARC viscosity or reduced bake time or temperature to remove a solvent of the BARC can aid the clumping process to exaggerate the asymmetry in deposition thickness. This clumping effect can lead to a somewhat greater thickness of the BARC over an upper surface of the patterned layer 304 relative to the bottom of the second openings 306. For example, the first distance 504 can be about 1400 angstroms, including about 1000 angstroms of the patterned layer and a fourth thickness 510 (or distance) of about 400 angstrom of BARC deposited above the patterned layer 304. The second thickness 506 can equal somewhat less than the fourth thickness 510 (e.g., about 300 angstrom). The difference in the thickness of the anti-reflective layer 502 can operate to substitute for a mask, by providing greater protection from a removal for the portions of the semiconductor device 200 covered by the thicker portions, relative to the thinner portions (e.g., the first region 206 or second region 208). Such an approach can thus omit a mask to define features for an alignment mark of the third region 210.

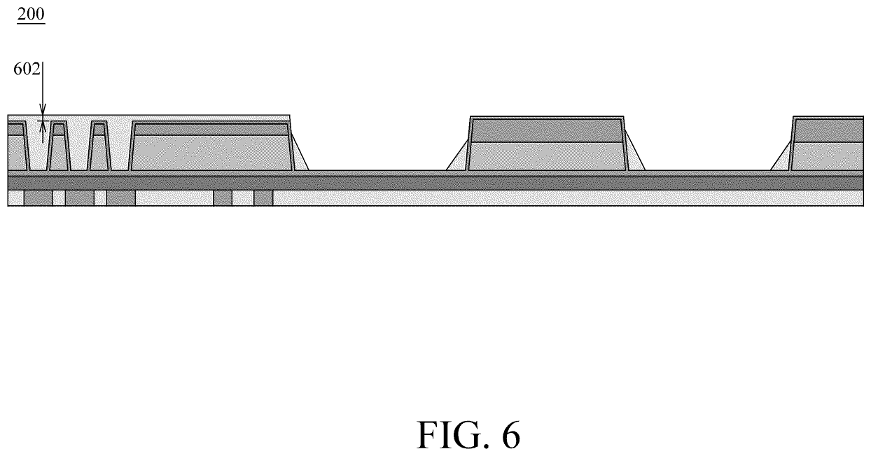

Corresponding to operation 110 of FIG. 1, FIG. 6 illustrates a semiconductor device 200 having an anti-reflective layer 502 removed (e.g., etched). The removal can be configured to remove a selected thickness of the anti-reflective layer 502, according to a time, number of cycles, etchant composition, or chamber conditions. For example, the removal can be configured to remove at least the second thickness 506 (over the second openings 316), but less than the fourth thickness 510 (over the patterned layer 304 proximal to the first openings 314). Such a removal can expose the second etch stop layer 402 in the bottom of the second openings 316. In some cases, a clumping effect can further lead to greater thickness of the anti-reflective layer 502 over portions of the patterned layer 304 proximal to the second opening 306, as may protect such an upper surface. However, these areas may be provided as keep out areas for electrical connections, such that some damage to the patterned layer 304 in this region may be acceptable. A fifth thickness 602 (or distance) of about 50-100 angstroms of the anti-reflective layer 502 can remain over the etch stop layer 402 formed over the patterned layer 304 defining the first openings 314. Moreover, portions of the anti-reflective layer 502 can remain along the sidewalls of the second openings 316 (and covering the first openings to at least an upper surface of the second etch stop layer 402 formed over the patterned layer 304). Such a remaining portion of the anti-reflective layer 502 can reduce an impact of under-etch, where a wet process is used for removal of any of the hardmask 312, the low-k dielectric 212, or the etch stop layers.

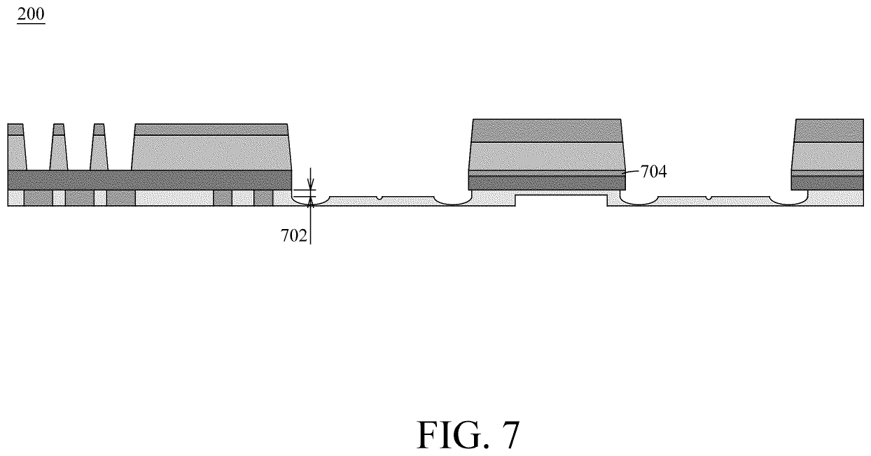

With continued correspondence to operation 110 of FIG. 1, FIG. 7 illustrates a further removal (e.g., etch) operation, whereby the exposed second etch stop layer 402 of FIG. 6 is removed, along with a first etch stop layer 302 formed thereunder. For example, a dry etch process can be applied to remove the second etch stop layer 402 and the first etch stop layer 302 (which can form a single, combined layer). The operation can further remove a portion of the anti-reflective layer 502 over the first region 206. However, the combination of the thickness of the fifth thickness 602 of the remaining anti-reflective layer 502 with the second etch stop layer 402 which the anti-reflective layer 502 is formed over can protect the patterned layer 304 (e.g., at least the ILD of the patterned layer 304) during an etching process used to remove the first etch stop layer 302 and second etch stop layer 402 at the bottom of the second openings 316.

The same etching process (or another removal process) can remove all or a portion of the silicon-based layer or other hardmask 312, and may extend into the low-k dielectric 212. For example, about 300 angstroms of the low-k dielectric 212 can be removed. In some embodiments, the removal can be performed according to a multi-step process. For example, a first suboperation of a dry etch can break through the first etch stop layer 302 and second etch stop layer 402, and a second suboperation can extend the opening into the hardmask 312 and low-k dielectric 212. The second suboperation can include a somewhat isotropic etch, as can under-etch the hardmask 312, such that a sidewall of the second openings 316 for the alignment mark extends laterally under the hardmask 312 (e.g., under the silicon-based layer).

Subsequent to the breakthrough of the first etch stop layer 302 and the second etch stop layer 402, any remaining portions of the anti-reflective layer 502 can be removed. For example, an oxygen-, nitrogen-, or ammonia-based plasma can be used to remove the remaining portions of the anti-reflective layer 502 (sometimes referred to as a plasma stripping process). Because alignment markings will be formed over the exposed low-k dielectric 212 at the bottom of the second openings, carbon depletion, pore collapse, or other damage to the exposed low-k dielectric 212 should not impact circuit operation. Indeed, such operation may further extend the etchant depth into the exposed low-k dielectric 212, increasing an ultimate thickness of an alignment mark. The etch can be selective to other portions of the semiconductor device 200 (e.g., the USG or other ILD), to reduce a removal or damage to these portions.

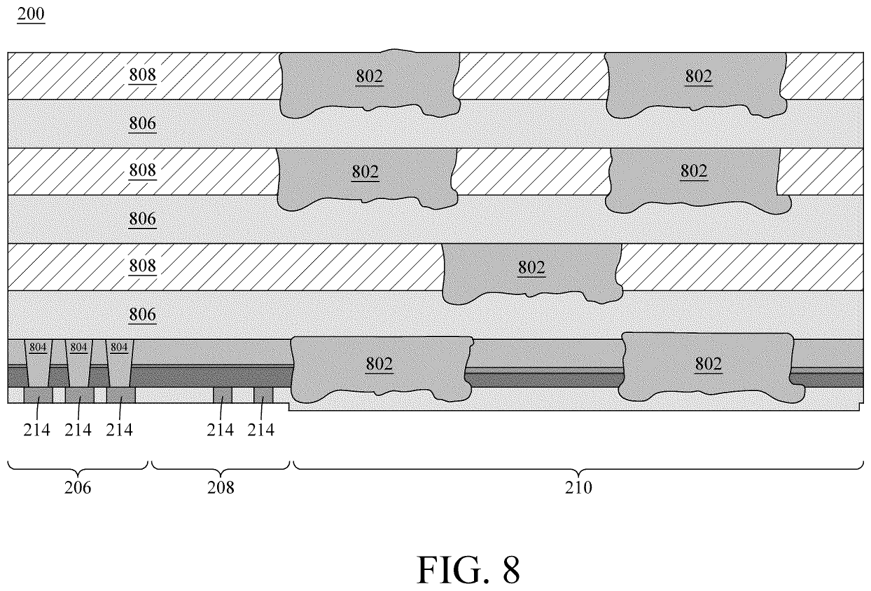

FIG. 8 illustrates an example cross sectional view of a semiconductor device 200 including stacked layers. For example, the depicted semiconductor device 200 can be formed according to the method 100 of FIG. 1. In some embodiments, the method 100 can form one or more alignment marks 802 at a same layer of a semiconductor device 200. In some embodiments, the method 100 can be repeated to form multiple stacked layers, each having at least one alignment mark 802. For example, the method 100 can be repeated to form stacks of a memory device including tens, hundreds, or thousands or layers.

The via structures 214 vertically extending through the first region 206 are coupled with further via structures or other interconnects 804. The interconnects 804 are depicted as a single interconnect 804 extending along a sidewall which, like the alignment marks 802, abuts an inter-layer dielectric of the patterned layer 304, a silicon-based layer or other hardmask 312, a first etch strop layer 302 (e.g., an aluminum-oxide layer), and a low-k dielectric layer 212. However, interconnections can be formed according to multiple metallization layers including conductive lines interconnected by further via structures, or other inter-layer via structures. For example, the via structures 214 vertically extending through the first region 206 are depicted without interconnects 804 in the depicted cut plane. Such a depiction can correspond to interconnects 804 provided on another plane, or a lack of interconnects 804 extending through the inter-layer dielectric of the patterned layer 304 for at least some portions of the circuits of the second region 208.

Further layers can be stacked over the depicted upper surface (e.g., backside of the substrate 202) of the semiconductor device 200. For example, alternating dielectric layers 806 and active layers 808 can be stacked over one another. Like the inter-layer dielectric provided according to the illustrative example of a low-k dielectric 212 in FIGS. 2-7, the dielectric layers 806 can include various dielectrics, as may include silicon dioxide or a low-k dielectric (e.g., an extreme low-k dielectric). The active layers 808 can include further substrates, as in the case of die or wafer bonding, or film-based layers as may be used to provide additional memory cells or logic functions to be coupled with an active surface of the first substrate 202. For example, film-based layers can be applied over a surface (e.g., a backside) of a substrate 202 to form a stacked memory device. The substrate or film-based layers can include a patterned layer 304, etch stop layer, or hardmask 312, such that openings for the alignment marks 802 formed in the stacked layers can be formed according to a similar technique as for the second openings 316 of FIGS. 2-7.

The alignment marks 802 can be formed over one another, according to a uniform lateral placement, as depicted with regard to the uppermost two active layers 808, or can be staggered or otherwise offset from one another, as depicted with regard to the lowermost three layers of the alignment marks 802. The alignment marks 802 can include various materials from a marking layer configured to be detected according to a contrast with another portion of the semiconductor device. Accordingly, the alignment marks 802 can exhibit discernable contrast as viewed optically (in the visual or IR spectrum), by a scanning electron beam, or otherwise. For example, the alignment marks 802 can include high-Z metals such as tungsten or molybdenum as can provide contrast against anti-reflective coatings, mask layers, dielectric stack, or other metals for an extreme ultraviolet process. The alignment marks 802 can include titanium nitride, tungsten, etched silicon nitride to provide contrast against various dielectric layers of a chemical mechanical grinding or polishing process (CMP/G). Various further materials are contemplated as may correspond with further processes still, or according to a base layer that the alignment mark 802 is configured to contrast with.

An upper surface of the alignment mark can be provided as relatively level from a CMP/G or other process to plane an upper surface. A lower surface of the alignment mark can exhibit greater irregularity, according to an isotropic process used to etch the opening at operation 110, or according to a shadowing effect of a remining portion of the anti-reflective coating 502, as depicted in FIG. 6. However, a thickness (e.g., an average, maximum, or minimum total thickness) of the alignment mark 802 exceed about 800 angstroms, as may exceed a thickness realized according to other approaches. Such a dimension can improve detectability of the alignment mark, and improve stacking alignment according to placements adjusted to the improved precision of detection.

In one aspect of the present disclosure, a method of semiconductor device fabrication is provided. The method includes forming a first etch stop layer over a substrate. The method includes forming an inter-layer dielectric over the etch stop layer. The method includes patterning the inter-layer dielectric to form a first opening and a second opening. The method includes forming a second etch stop layer over the patterned inter-layer dielectric. The method includes forming an anti-reflective layer over the first etch stop layer, the anti-reflective layer having a first thickness over the first opening, and a second thickness, greater than the first thickness, over the second opening. The method includes etching the anti-reflective layer to expose a bottom surface of the second opening and not a bottom surface of the first opening without masking the first opening.

In another aspect of the present disclosure, a method of semiconductor device fabrication is provided. The method includes providing a substrate comprising a plurality of memory cells. The method includes forming a first aluminum oxide layer over the substrate. The method includes forming a patterned layer over the first aluminum oxide layer, the patterned layer comprising a plurality of first openings spaced over the memory cells and a plurality of second openings laterally spaced from the plurality of first openings. The method includes forming a second aluminum oxide layer over the patterned layer. The method includes forming an anti-reflective layer over the second aluminum oxide layer, the anti-reflective layer having a first thickness over the plurality of first openings and a second thickness, greater than the first thickness, over the plurality of second openings. The method includes etching the anti-reflective layer in the plurality of second openings to expose at least one of the aluminum oxide layers.

In another aspect of the present disclosure, a semiconductor device is provided. The semiconductor device includes a plurality of memory cells (e.g., stacked memory cells). The semiconductor device includes an alignment mark laterally offset from the plurality of memory cells. The alignment mark abuts, along a sidewall, an inter-layer dielectric, a silicon-based layer, a first aluminum-oxide layer, and a low-k dielectric layer spacing the stacked memory cells from one-another. The memory cells can be stacked according to the alignment mark.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of semiconductor device fabrication, comprising:
forming a first etch stop layer over a substrate;
forming an inter-layer dielectric over the first etch stop layer;
patterning the inter-layer dielectric to form a patterned layer including a first opening and a second opening;
forming a second etch stop layer over the patterned layer;
forming an anti-reflective layer over the second etch stop layer, the anti-reflective layer having a first thickness over the first opening, and a second thickness, less than the first thickness, over the second opening; and
etching the anti-reflective layer to expose a bottom surface of the second opening, the anti-reflective layer covering the bottom surface of the first opening.

2. The method of claim 1, wherein forming the anti-reflective layer comprises:
forming the anti-reflective layer having a third thickness, less than the first thickness and greater than the second thickness, over an upper surface of the patterned layer.

3. The method of claim 1, wherein the etched anti-reflective layer covers an upper surface of the patterned layer abutting the first opening.

4. The method of claim 1, wherein etching the anti-reflective layer removes the anti-reflective layer from a bottom surface of the second opening and leaves the anti-reflective layer on at least a portion of sidewalls of the second opening.

5. The method of claim 4, further comprising:
removing, according to an isotropic process:
the remaining portion of the anti-reflective layer from the sidewalls of the second opening;
a silicon-based layer under the first etch stop layers and the second etch stop layer; and
a low-k dielectric layer under the silicon-based layer.

6. The method of claim 1, further comprising:
forming a plurality of layers of a memory device over the first opening.

7. The method of claim 1, further comprising:
removing, using a plasma stripping process, the anti-reflective layer from the first opening; and
removing the first etch stop layer and the second etch stop layer from a lower surface of the first opening.

8. A method of semiconductor device fabrication, comprising:
providing a substrate comprising a plurality of memory cells;
forming a first cap layer over the substrate;
forming a patterned layer over the first cap layer, the patterned layer comprising a plurality of first openings spaced over the plurality of memory cells and a plurality of second openings laterally spaced from the plurality of first openings;
forming a second cap layer over the patterned layer;
forming an anti-reflective layer over the second cap layer, the anti-reflective layer having a first thickness over the plurality of first openings and a second thickness, greater than the first thickness, over the plurality of second openings; and
etching the anti-reflective layer in the plurality of second openings to expose at least one of the cap layers.

9. The method of claim 8, wherein the plurality of second openings are of greater lateral dimension than the plurality of first openings.

10. The method of claim 9, wherein the anti-reflective layer is an organic backside anti-reflective coating (oBARC) formed according to a spin-coating process to form the second thickness as greater than the first thickness.

11. The method of claim 8, wherein the first cap layer is an aluminum oxide layer thicker than aluminum oxide of the second cap layer.

12. The method of claim 8, wherein etching the anti-reflective layer in the plurality of second openings leaves the anti-reflective layer in the plurality of first openings.

13. The method of claim 8, wherein etching the anti-reflective layer in the plurality of second openings leaves the anti-reflective layer on an upper surface of the patterned layer.

14. The method of claim 13, wherein etching the anti-reflective layer further etches through a low-k dielectric layer.

15. The method of claim 8, further comprising:
forming via structures in the plurality of first openings to interconnect the plurality of memory cells with a plurality of second memory cells of a second layer of the semiconductor device; and
forming a marking layer in the plurality of second openings.

16. The method of claim 15, wherein the via structures are backside via structures of the semiconductor device.

17. The method of claim 15, wherein the marking layer has a thickness exceeding 800 Angstroms.

18. The method of claim 8, further comprising:
removing the anti-reflective layer, the first cap layer, and the second cap layer from the patterned layer subsequent to etching the anti-reflective layer in the plurality of second openings.

19. A semiconductor device comprising:
a plurality of memory cells; and
an alignment mark laterally offset from the plurality memory cells, wherein the alignment mark has a thickness exceeding about 800 Angstroms and abuts, along a sidewall:
an inter-layer dielectric;
a silicon-based layer;
a first etch stop layer; and
a low-k dielectric layer vertically spacing the memory cells from one-another.

20. The semiconductor device of claim 19, wherein the sidewall extends laterally under the silicon-based layer.
